(19) United States
(12) Patent Application Publication
(10) Pub. No.: US 2016/0133477 A1
(43) Pub. Date: May 12, 2016

(54) METHODS OF FORMING RELIEF IMAGES

(71) Applicants: Rohm and Haas Electronic Materials, LLC, Marlborough, MA (US); Dow Global Technologies LLC, Midland, MI (US)

(72) Inventors: Peter Trefonas, III, Medway, MA (US); Phillip Hustad, Natick, MA (US); Jieqian Zhang, Southborough, MA (US); James C. Taylor, Wilton, NY (US)

(21) Appl. No.: 14/934,628

(22) Filed: Nov. 6, 2015

Related U.S. Application Data
(60) Provisional application No. 62/077,104, filed on Nov. 7, 2014.

(51) Int. Cl. H01L 21/308; H01L 21/027

(52) U.S. Cl. CPC H01L 21/3086; H01L 21/3081; H01L 21/0273

(57) ABSTRACT

In a preferred aspect, methods are provided that comprise a) providing a semiconductor substrate comprising a patterned mask over a layer to be patterned; b) applying a layer of a first composition over the mask, wherein the composition comprises a polymer and the layer is coated on a sidewall of the mask; c) applying a layer of a second composition over the semiconductor substrate in a volume adjacent the coated sidewall of the mask; and d) removing the first composition from the sidewall of the mask, thereby exposing the layer to be patterned and forming a gap between the mask sidewall and the second composition layer to provide a relief image. The methods find particular applicability in semiconductor device manufacture.

### BACKGROUND

This disclosure relates generally to the manufacture of electronic devices. More specifically, this disclosure relates to methods of forming photolithographic patterns. The invention finds particular use in the manufacture of semiconductor devices for forming high-density lithographic patterns and features.

In the semiconductor manufacturing industry, photoresist materials are used for transferring an image to one or more underlying layers, such as metal, semiconductor or dielectric layers, disposed on a semiconductor substrate, as well as to the substrate itself. To increase the integration density of semiconductor devices and allow for the formation of structures having dimensions in the nanometer range, photoresists and photolithography processing tools having high-resolution capabilities have been and continue to be developed.

One approach to achieving nm-scale feature sizes in semiconductor devices is the use of short wavelengths of light, for example, 193 nm or less, during exposure of chemically amplified photoresists. Immersion lithography effectively increases the numerical aperture of the lens of the imaging device, for example, a scanner having a KrF or ArF light source. This is accomplished by use of a relatively high refractive index fluid (i.e., an immersion fluid) between the last surface of the imaging device and the upper surface of the semiconductor wafer. The immersion fluid allows a greater amount of light to be focused into the resist layer than would occur with an air or inert gas medium.

The theoretical resolution limit as defined by the Rayleigh equation R=k₁λ/NA where k₁ is the process factor, λ, is the wavelength of the imaging tool and NA is the numerical aperture of the imaging lens. When using water as the immersion fluid, the maximum numerical aperture can be increased, for example, from 1.2 to 1.35. For a k₁ of 0.25 in the case of printing line and space patterns, 193 nm immersion scanners would only be capable of resolving 36 nm half-pitch line and space patterns. The resolution for printing contact holes or arbitrary 2D patterns is further limited due to the low aerial image contrast with a dark field mask wherein the theoretical limit for k1 is 0.35. The smallest half-pitch of contact holes is thus limited to about 50 nm. The standard immersion lithography process is generally not suitable for manufacture of devices requiring greater resolution.

In an effort to achieve greater resolution and to extend capabilities of existing manufacturing tools beyond theoretical resolution limits, various double patterning processes have been proposed, for example, self-aligned double patterning (SADP), litho-etch-litho-etch (LELE) and litho-litho-etch (LLE) techniques. Such techniques as typically implemented, however, suffer from one or more disadvantages. SADP processes typically involve a relatively large number of process steps, thereby adversely affecting production throughput. Product contamination and defectivity can result from LELE techniques from transport of wafers back and forth between photolithography and etching processing modules, and from etching and resist removal processes themselves. LLE procedures involve formation and stabilization of a first lithographic (L1) resist pattern followed by formation of a second lithographic (L2) pattern. See U.S. Pat. No. 8,492,075; U.S. 20140054756; and Hyatt, et al. Proc. SPIE 9051, 905118 (2014).

It is therefore desirable to have new methods to produce fine microlithography features.

### SUMMARY

We now provide new methods for forming relief images useful for producing electronic devices. In a preferred aspect, methods for forming a relief image are provided that comprise: a) providing a semiconductor substrate comprising a patterned mask over a layer to be patterned; b) applying a layer of a first composition over the mask, wherein the composition comprises a polymer and the layer is coated on a sidewall of the mask; c) applying a layer of a second composition over the semiconductor substrate in a volume adjacent the coated sidewall of the mask; and d) removing the first composition from the sidewall of the mask, thereby exposing the layer to be patterned and forming a gap between the mask sidewall and the second composition layer to provide a relief image.

Methods of the invention can provide self-aligned spaces of small dimensions including 20 nm or less next to lithography defined patterns.

Additionally, in one aspect, preferred methods disclosed herein are distinguished from prior self-aligned patterning techniques that create lines, which then require multiple steps to reverse the pattern and create spaces. Instead, in present preferred methods, self-aligned spaces can be directly created without the formation of corresponding lines.

In a further aspect, preferred methods of the invention utilize coating materials of differing etch rates. Thus, in a preferred aspect, sidewalls of a lithographically defined feature are coated with a polymeric material that has a sufficiently faster etch rate than that of the material (e.g. an organic silicon polymer layer) comprising the feature and of an additional material which is used to fill the remaining spaces between the coated original features. This faster etch rate allows the polymer spacer to be removed quickly without significantly changing the shape and profile of the remaining structures, leaving a space. Again, the formed spaces may be of small dimensions, including widths of 20 nm or less.

In preferred methods, the patterned mask comprises one or more materials that will be reactive to the subsequently applied first composition. For instance, preferably, the surface of the mask pattern may comprise one or more materials that can bond or otherwise complex or coordinate to the overcoating first composition. For instance, preferred components of the mask pattern that may bond or coordinate include silicon such as SiO₂, SiON, anti-reflective coating compositions, amorphous carbon, spin-on carbon hard mask, or other carbon based materials, and oxides of titanium, hafnium, and/or zirconium. Cured antireflective coating compositions are preferred for at least certain applications, e.g. cured silicon-containing antireflective coating compositions, including cured organic silicon antireflective coating compositions.

Additionally, the patterned mask suitably has an etch rate that is less than the etch rate of the subsequently applied first composition, for example, where the etch rate of the patterned mask is at least 20, 30, 40, 50, 60, 70 or 80 percent less than the etch rate of the subsequently applied first composition.

A variety of materials may be employed as the first composition. Preferred first compositions may contain one or more polymers. Particularly preferred first compositions comprise one or more components (e.g. polymers) that can bond (e.g. covalent linkage) or otherwise complex or coordinate (e.g. hydrogen or ionic bond) to one or more materials present on the patterned mask sidewalls. For instance, a component that comprises an appropriate reactive moiety at one chain end, i.e. a hydroxyl end group for the case of oxide features, to allow for covalent attachment to the patterned mask side walls.

Preferred first compositions comprise one or more polymers that have a molecular weight appropriate to form a film with thickness of 20 nm or less. For instance, suitable first composition polymers may have a weight average molecular weight of 5,000 to 100,000. Preferred first composition polymer components also will be thermodynamically inclined to form a smooth film of uniform film thickness. Still further, preferred first composition polymers will have an Ohnishi parameter (O.P.), defined as the ratio of the total number of atoms in a repeat unit of the polymer chain (N) to the difference between the total number of carbon atoms (N_{C}) and total number of oxygen atoms (N_{O}) in the same repeat unit, O.P.=N/(N_{C}−N_{O})), greater than 2 for sufficiently fast etch rate in common organic etch processes, i.e. O₂ or N₂/H₂ plasma etch processes. In embodiments where the first patterned mask is formed from carbon-based materials such as amorphous carbon or spin-on carbon hard masks, preferred first composition polymers include polymers comprising silicon which have a fast etch rate relative to the carbon mask. Polymeric brush compositions such as a hydroxyl-containing composition are often preferred first composition materials.

In preferred methods, after applying the first composition over the patterned mask, the coated substrate is treated to create a relief image of the patterned mask having the first composition coated on the sidewalls thereof. For instance, after the first composition is applied over the substrate with patterned mask, the applied first composition may be optionally but preferably processed such as by thermal treatment (e.g. 150° C. or greater for 1, 5, 10 minutes or more) to induce bonding of a portion of the first composition to the sidewall of the mask. After such processing, the substrate may be washed such as with a solvent to remove the first composition that is not bonded to or otherwise complexed to the patterned mask sidewalls. The coated substrate also may be treated by other means to remove the first composition that is not bonded to or complexed to the patterned mask sidewalls. For instance, the coated substrate may be etched to remove the first composition in such manner.

In preferred methods, the second composition can be cast into a planarizing film of uniform thickness over the topography created by the original features with the first composition. Preferably, the second composition has a reactive ion etch rate that is less than the reactive ion rate of the first composition, for example, where the reaction ion etch rate of the second composition is at least 20, 30, 40, 50, 60, 70 or 80 percent less than the reactive ion rate of the subsequently applied first composition.

Thereafter, the first composition can be removed from the sidewalls of the mask to thereby provide multiple relief images. Removal of the first composition can bare the underlying layer to be patterned and form a gap between the mask sidewall and the second composition layer to provide a relief image.

Preferably, the substrate or film at the interface between the original features and the rest of the substrate stack should be of a material that is substantially unreactive to the reactive groups of the first composition as well as substantially neutral to the first composition, to ensure there is neither selective wetting or dewetting of the first composition to the substrate, thereby providing even coverage of the original features.

In additional aspects, coated substrates are provided. In a preferred aspect, a coated substrate is provided comprising: a semiconductor substrate comprising a patterned mask over a layer to be patterned; a layer of a first composition over the mask, wherein the composition comprises a polymer brush and the layer is coated on a sidewall of the mask; and a second composition over the semiconductor substrate in a volume adjacent the coated sidewall of the mask, wherein the etch rate of the first composition is at least 30 percent greater than the etch rate of each of the 1) first composition and 2) second composition. Preferably, the etch rate of the first composition is at least 40, 50, 60, 70, 80, 90 or 100 percent greater than the etch rate of each of the 1) first composition and 2) second composition.

In a further preferred aspect, a coated substrate is provided that comprises 1) a semiconductor substrate comprising a patterned mask over a layer to be patterned; 2) a layer of a first composition over the mask, wherein the composition comprises a polymer brush and the layer is coated on a sidewall of the mask; and 3) a second composition over the semiconductor substrate in a volume adjacent the coated sidewall of the mask wherein the second composition forms a single phase adjacent to the first composition layer. As should be understood, a single phase composition is distinguished from immiscible polymer blends that contain phase-separated polymers, or block copolymers that form a micro-separated layer.

As referred to herein, unless otherwise indicated, the term etch rate means the etch rate of a composition (in particular, the etch rate of each of a patterned mask, first composition and second composition) as determined by the following protocol: a coating layer of the composition is spin coated onto a 200 mm silicon wafer using an ACT8 coating tool. Spin speeds vary as necessary to obtain film thickness greater than 100 nm. Cure conditions are 215° C. for 60 seconds on a proximity hotplate. Film thickness is measured by ellipsometry. The films are then subjected to a selected blanket etch for a selected time such as for 30 seconds. The etching material is selected as an effective etchant for the first composition. Thus, for instance, if the first composition is substantially carbon-based, an oxide-based etch is suitably utilized for the etch rate analysis such as a blanket oxide etch (C₄F₈/O₂/CO/Ar). If the first composition is substantially silicon-based, a halogen-based etch (e.g. fluorine etch) is suitably utilized for the etch rate analysis. In assessing etch rates between two compositions (e.g. between a patterned mask and a first composition), the same etching material would be used for both materials (i.e. the same etching material would be used to assess etch rates of both the patterned mask and the first composition). After etching, the thickness of the etched films is re-measured and an etch rate calculated.

### BRIEF DESCRIPTION OF THE FIGURES

FIG. 1 (includes FIGS. 1A through 1D) is a schematic that depicts a preferred method of the invention.

FIG. 2 is a SEM micrograph of the line/space of Example 7.

FIGS. 3(a) and (b) show the pattern multiplication process from Example 8 using PS-OH brush as anti-spacer generator (first composition), including; (a) the pattern after treatment with PS-OH brush, and (b) final pattern after brush treatment, backfill, and removal of the brush polymer to form self aligned spaces.

FIGS. 4(a) and (b) show the pattern multiplication process from Example 9 using PS-OH brush as anti-spacer generator (first composition), including; (a) the pattern after treatment with PS-OH brush, and (b) final pattern after brush treatment, backfill, and removal of the brush polymer to form self aligned spaces.

FIGS. 5(a) and (b) show the pattern multiplication process from Example 10 using PMMA-OH brush as anti-spacer generator (first composition), including; (a) pattern after treatment with PMMA-OH brush, and (b) final pattern after brush treatment, backfill, and removal of the brush polymer to form self aligned spaces.

FIGS. 6(a) and (b) show the pattern multiplication process from Example 11 using PMMA-OH brush as anti-spacer generator (first composition), including; (a) pattern after treatment with PMMA-OH brush, and (b) final pattern after brush treatment, backfill, and removal of the brush polymer to form self aligned spaces.

### DETAILED DESCRIPTION

Preferred methods of the invention include forming multiple relief images, comprising: a) providing a semiconductor substrate comprising a patterned mask; b) applying a layer of a first composition over the mask; c) forming a relief image of the mask with the first composition layer on the surface of the mask relief image; d) applying a second composition on the semiconductor substrate; and e) removing the first composition layer to provide relief images of both the mask and the second composition.

In another preferred aspect, methods are provided are provide to form a relief image, comprising: a) providing a semiconductor substrate comprising a patterned mask over a layer to be patterned; b) applying a layer of a first composition over the mask; c) processing the applied first composition to induce bonding of a portion of the first composition to the sidewall of the mask; d) after the processing, removing the unbounded portion of the first composition; e) applying a layer of a second composition over the semiconductor substrate in a volume adjacent the coated sidewall of the mask; and f) removing the first composition from the sidewall of the mask, thereby exposing the layer to be patterned and forming a gap between the mask sidewall and the second composition layer to provide a relief image.

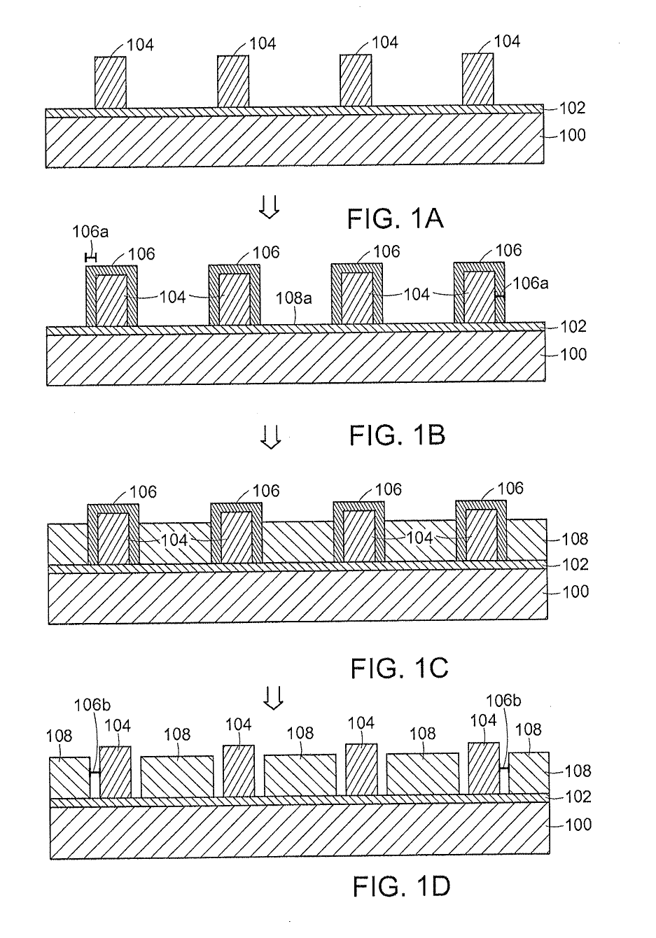

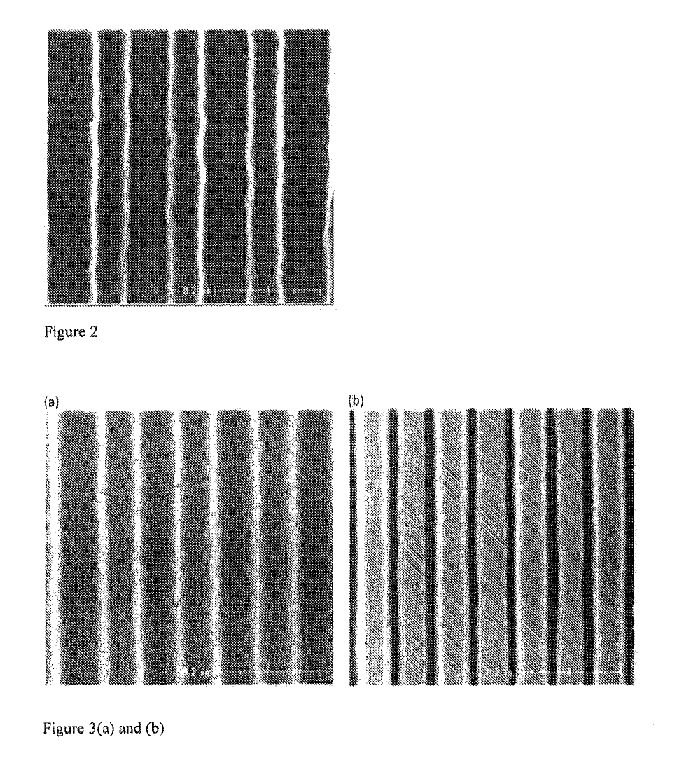

### FIG. 1A

Referring now to FIG. 1A, substrate 100 is depicted which may include various layers and features formed on a surface thereof. The substrate can be of a material such as a semiconductor, such as silicon or a compound semiconductor (e.g., III-V or II-VI), glass, quartz, ceramic, copper and the like. Typically, the substrate is a semiconductor wafer, such as single crystal silicon or compound semiconductor wafer, and may have one or more layers and patterned features formed on a surface thereof. One or more layers 102 to be patterned may be provided over the substrate 100. Optionally, the underlying base substrate material itself may be patterned, for example, when it is desired to form trenches in the substrate material. In the case of patterning the base substrate material itself, the pattern shall be considered to be formed in a layer of the substrate.

The layers may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. The layers to be etched can be formed by various techniques, for example: chemical vapor deposition (CVD) such as plasma-enhanced CVD, low-pressure CVD or epitaxial growth; physical vapor deposition (PVD) such as sputtering or evaporation; or electroplating.

Patterned mask 104 may be provided by a number of approaches.

For instance, a photoresist composition may be suitably applied on the substrate over an antireflective layer. The antireflective layer may suitably comprise a material that can covalently bond or otherwise coordinate to a subsequently applied first composition. Thus, for instance, the antireflective composition may comprise a silicon component such as a silicon-organic polymer, titanium, hafnium, and/or zirconium.

A variety of photoresists can be employed including those based on acrylate, novolak and silicon chemistries. Suitable resists are described, for example, in U.S. Application Publication Nos. US20090117489 A1, US20080193872 A1, US20060246373 A1, US20090117489 A1, US20090123869 A1 and U.S. Pat. No. 7,332,616. The photoresist materials useful in the methods of the invention for forming a first resist pattern include both positive- and negative-acting materials. Suitable positive-acting materials include positive-acting chemically amplified photoresists which undergo a photoacid-promoted deprotection reaction of acid labile groups of one or more components of the composition to render exposed regions of a coating layer of the resist more soluble in an aqueous developer than unexposed regions. Suitable negative-acting resists typically will contain a crosslinking component. Alternatively, a positive-acting resist can be exposed and the unexposed regions can be removed with an organic solvent to leave behind the exposed regions in a so-called “negative tone develop” process.

The photoresist then may be lithographically processed by exposure and development steps as further discussed below to create a relief image of spaced resist features. The bared antireflective composition then can be removed by reactive ion etching. Subsequent stripping of the photoresist relief image provides a patterned mask 104 formed of the etched antireflective layer.

Alternatively, an imaged and developed photoresist layer may serve as the patterned mask 104. For instance, carboxylic acid groups present in one or more components of the photoresist layer may covalently bond or otherwise coordinate with functionalities of the subsequently applied first composition. For instance, the first composition may comprise an amine-containing material that may complex with carboxylic acid groups of a photoresist composition component.

A photoresist composition can be applied to the substrate 100 with one or more overcoated layers by known methods and then imaged and developed to provide resist relief image 104. For instance, a photoresist coating layer can be applied to the substrate surface by spin-coating or other conventional coating technique. The applied resist layer then may be softbaked to minimize the solvent content in the resist layer. The resist layer is next exposed to patterned activating radiation, e.g. 193 nm or EUV radiation. An immersion lithography protocol also may be suitably employed. Following exposure of the photoresist layer, a post-exposure bake (PEB) is typically performed at a temperature above the softening point of the layer, e.g. from about 80 to 150° C. for about 30 to 90 seconds. The exposed photoresist layer is next developed to form a resist pattern. Suitable developers and development techniques are known in the art and include, for example, aqueous base developers such as quaternary ammonium hydroxide solutions, for example, tetra-alkyl ammonium hydroxide solutions such as 0.26 N tetramethylammonium hydroxide.

### FIG. 1B

As shown in FIG. 1B, patterned mask 104 is suitably selectively coated with first composition 106. As discussed, the patterned mask 104 suitably has an etch rate that is less than the etch rate of the subsequently applied first composition, for example, where the etch rate of the patterned mask is at least 20, 30, 40, 50, 60, 70 or 80 percent less than the etch rate of the subsequently applied first composition.

A variety of materials may be employed as the first composition. Preferred first compositions may contain one or more polymers. Particularly preferred first compositions comprise one or more components (e.g. polymers) that can bond (e.g. covalent linkage) or otherwise complex or coordinate (e.g. hydrogen or ionic bond) to one or more materials present on the patterned mask sidewalls. For instance, a component that comprises an appropriate reactive moiety at one chain end or along the main chain, i.e. a hydroxyl end group for the case of oxide features, to allow for covalent attachment to the patterned mask side walls. The component also can be a polymer or copolymer containing more than one reactive group to allow attachment.

Particularly preferred first compositions include polymer brush compositions. The term “brush composition” or “brush layer” is utilized herein to refer to a layer formed by covalent or coordinate (e.g. hydrogen or ionic bond) bonding of a polymeric organic material to a surface. In some embodiments, the brush layer may comprise a siloxane; and may be formed from a siloxane-containing precursor such as, for example, a precursor comprising poly(dimethylsiloxane) (PDMS). In some embodiments, the brush layer may be formed from precursors comprising other organic polymers either in addition to, or alternatively to, siloxane-containing polymers. For example, the brush layer may be formed utilizing precursors comprising one or both of polystyrene (PS) and poly(methylmethacrylate) (PMMA). The brush layer precursors have one or more substituents suitable for reacting with surfaces to thereby covalently bond (i.e., graft) the brush layer to the surfaces. Such substituents may comprise hydroxyl moieties, sulfhydryl moieties, etc.

The first composition may be applied to substrate 100 with patterned mask 104 by any of a variety of techniques including spin coating. After applying a layer of the first composition, the coated substrate is then preferably thermally treated. Thermal treatment can enhance bonding or complexing of the first composition 106 to the sidewalls of the patterned mask 104. Suitable thermal treatment conditions may include heating in excess of 150° C. or 200° C. for 0.5 to 15 minutes depending on the specific materials utilized. First composition material that is unattached to patterned mask sidewalls following such thermal treatment then is suitably removed, for example by rinsing the coated substrate with a suitable solvent such as propylene glycol monomethyl ether acetate, n-butylacetate, or the like. Removal of unattached first composition material by such rinsing provides the patterned mask 104 with sidewalls coated with the first composition 106 as generally shown in FIG. 1B. Following removal of the unattached first composition material the substrate may be annealed if desired, for example by heating in excess of 150° C. or 200° C. for 1, 2 or more minutes.

We also have found that the first composition layer thickness 106a can be controlled through selection or tailoring of one or more components of the first composition. In particular, by selection of the molecular weight and/or blend ratios of one or more polymer components of the first composition, the coating layer thickness can be controlled and thereby the width of the formed spaces 106b (FIG. 1D) can be controlled. See, for instance, Example 6 which follows. In general, use of a higher molecular weight polymers as components of the first composition, including polymers that have a weight average molecular weight in excess of 8,000; 9,000; 10,000; 11,000; or 12,000, can enable forming greater first composition coating layer thicknesses 106a and thereby produce formed spaces 106b of greater widths.

### FIG. 1C

As shown in FIG. 1C, the substrate is coated with a second composition 108 that fills areas bared by patterned mask 104 with coated sidewalls 106 to fill the space 108a (FIG. 1B) with the second composition 108. Preferably, the second composition will be a homogeneous single phase. Preferably, the second composition has an etch rate that is less than the etch rate of the first composition, for example, where the etch rate of the second composition is at least 20, 30, 40, 50, 60, 70 or 80 percent less than the etch rate of the subsequently applied first composition. For example, suitable second compositions include silicon-containing compositions, for instance polydimethylsiloxane, silsesquioxanes, silicon-containing polyacrylates and polymethacrylates, silicon-containing polystyrenes, and other polymers containing silicon. Following coating with a second composition, the substrate may be annealed if desired, for example by heating in excess of 150° C. or 200° C. for 1, 2 or more minutes. Importantly, the first composition and the second composition are selected such that they are not miscible when heated but remain separated into discrete phases.

### FIG. 1D

As depicted in FIG. 1D, the first composition can be removed from the sidewalls of the mask such as by etching to thereby provide multiple relief images of the patterned mask 104 and second composition 108. Removal of the first composition can bare the underlying layer to be patterned and form a gap between the mask sidewall and the second composition layer 108 to provide a relief image with spaces 106b.

These materials and processes are useful for creating relief patterns with higher feature density than possible from single exposure photolithographic processes. Importantly, the resulting relief patterns are self aligned to the original mask pattern, thereby mitigating problems with overlay error inherent to comparative processes using multiple photolithographic exposures. These self-aligned relief patterns are also useful to form trenches for ion implantation and self-aligned line cut patterns.

The following non-limiting examples are illustrative of the invention.

### EXAMPLES

### Methods

The film thicknesses reported in the Examples herein were measured using a NanoSpec/AFT 2100 Film Thickness Measurement tool. The thickness of the films was determined from the interference of a white light passed through a diffraction grating. A standard program called “Polyimide on Silicon” was used to analyze the component wavelengths (380-780 nm) to determine the film thickness.

The number average molecular weight, M_{N}, and polydispersity values reported in the Examples were measured by gel permeation chromatography (GPC) on an Agilent 1100 series LC system equipped with an Agilent 1100 series refractive index and MiniDAWN light scattering detector (Wyatt Technology Co.). Samples were dissolved in HPCL grade THF at a concentration of approximately 1 mg/mL and filtered through at 0.20 μm syringe filter before injection through the two PLGel 300×7.5 mm Mixed C columns (5 mm, Polymer Laboratories, Inc.). A flow rate of 1 mL/min and temperature of 35° C. were maintained. The columns were calibrated with narrow molecular weight PS standards (EasiCal PS-2, Polymer Laboratories, Inc.).

Inverse-gated ¹³C+ NMR spectroscopy was performed on a Bruker Avance 400 MHz NMR spectrometer equipped with a cryoprobe. Polymers were dissolved in CDCl₃ in 10 mm NMR tubes at room temperature. 0.02 M chromium acetylacetonate (Cr(acac)₃) was added to shorten the acquisition time. The typical sample concentration was 0.35 g/2.8 mL. All measurements were taken without sample spinning at 25° C., acquisition of 4000-8000 scans, relaxation delay of 5 s, 90° pulse length of 12.1 μs, spectrum reference of 77.27 ppm for CDCl₃, spectrum center at 100 ppm, and spectral width of 300 ppm.

Imaging of the pattern was performed using an AMRAY 1910 Field Emission scanning electron microscope (SEM). The test samples were mounted on the SEM stage using double sided carbon tape and cleaned by blowing nitrogen prior to analysis. An image of each of the test samples was collected at 50,000× magnification.

### Example 1

### Synthesis of PMMA-OH-1

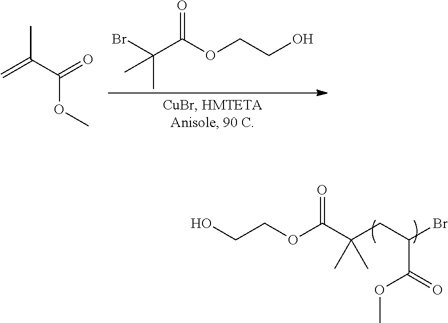

In a nitrogen-purged glovebox, methyl methacrylate (23.7 g, 237 mmol), CuBr (34.0 mg, 0.237 mmol), hexamethyltriethyltetramine (54.6 mg, 0.237 mmol), and the hydroxyl functionalized initiator (250 mg, 1.18 mmol) were combined in a dry 240 mL jar and subsequently diluted with 25 mL of dry anisole. A stir bar was added and the jar was capped and heated to 90° C. for 2 hours. The jar was then removed from the glovebox and cooled to room temperature. AMBERLITE IRC748I was added to the dark green solution and this was stirred at RT overnight. The now colorless solution was filtered to removed the AMBERLITE beads and the polymer was precipitated into MeOH, filtered and dried. It was then redissolved in 100 mL CH₂Cl₂ and washed 3× with DI water, then reprecipitated out of MeOH. The polymer was filtered and dried in a vacuum oven overnight at 60° C. The resulting polymer (11.2 g, 47.3%) was analyzed by GPC using a light scattering detector. The molecular weight was determined to be 13,800 g/mol with a PDI of 1.18.

### Example 2

### Synthesis of PMMA-OH-2

PMMA-OH-2 was synthesized using the above polymerization method modified to give material with Mn of 27.9 kg/mol and PDI of 1.21. PS-OH-1 was synthesized using the above polymerization method modified to give PS-OH-1 with Mn of 40 kg/mol and PDI of 1.23. PS-OH-2 was synthesized using the method described by Trefonas et al. in U.S. Pat. No. 8,822,615 modified to give PS-OH-2 with Mn of 9 kg/mol and PDI of 1.23.

### Example 3

### Synthesis of PtBS-18.8k

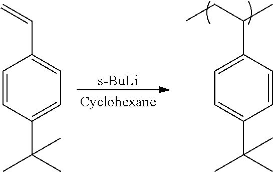

In a nitrogen-purged glovebox, 4-^{t}Bu styrene (22.4 g, 140 mmol) was added to a dry 250 mL round bottom flask and subsequently diluted with 125 mL of dry cyclohexane. While stirring via magnetic stir bar, s-BuLi (0.800 mL of a 1.40 M solution, 1.12 mmol) was added which caused an immediate color change to orange. This solution was left stirring at room temperature in the glovebox for 45 min before being quenched with a few drops of MeOH and removed from the glovebox. The polymer was precipitated into MeOH (600 mL), filtered and dried. It was then redissolved in 100 mL CH₂Cl₂ and washed 3× with DI water, then reprecipitated out of MeOH. The polymer was filtered and dried in a vacuum oven overnight at 80° C. The resulting polymer (19.4 g, 86.6%) was analyzed by GPC using a light scattering detector. The molecular weight was determined to be 18,800 g/mol with a PDI of 1.05.

### Example 4

### Preparation of SiARC-1

A silicon antireflective coating (SiARC-1) was prepared by dissolving a siloxane terpolymer composed of tetraethyl orthosilicate, phenyl trimethyloxysilane, vinyl trimethyloxysilane, and methyl trimethyloxysilane (in a ratio of 50/9/15/26 by weight) (58.5 g) and tetramethylammonium chloride (0.66 g) in a mixture of propylene glycol monomethyl ether acetate (250.7 g), ethyl lactate (15.5 g), oleyl alcohol (0.32 g), and 30 wt % nitric acid in water (4.3 g).

### Example 5

### Additional Materials

PS homopolymer was purchased from polymer source. (P2459-S, Mn=33 k, PDI=1.04). PDMS homopolymer was purchased from Gelest. (IC-8502, Mn=9 k).

### Example 6

### Control of Anti-Spacer Generator (First Composition) Thickness

Solutions of 2 wt % PS-OH-1 and PS-OH-2 were prepared in propylene glycol monomethyl ether acetate (PGMEA). Additional solutions were prepared to form mixtures of PS-OH-1 and PS-OH-2 at 25 vol %, 50 vol %, and 75 vol % of PS-OH-1. These five solutions were applied as films to silicon wafers by spin coating at 1500 rpm and baking at 250° C. for 2 min in air. Unattached PS-OH was then removed by rinsing the pattern twice with PGMEA and spinning dry, and the residual thickness was measured (Table 1). The thickness depended on the molecular weight of the PS-OH, as PS-OH-1 with Mn=40 kg/mol gave a 12.1 nm film while PS-OH-2 with Mn=9 kg/mol gave a 6.4 nm film. The thickness was additionally controlled by blending these two PS-OH materials, as increasing amount of PS-OH-2 gave a concomitantly thinner residual film. This example demonstrates the ability to control the thickness of the anti-spacer generator by modification of the polymer molecular weight or blending.

TABLE 1

| | Polymer 1 | | Polymer 2 | Grafted |
|---|---|---|---|---|
| Polymer 1 | (vol %) | Polymer 2 | (vol %) | Thickness (nm) |
| PS-OH-1 | 100 | PS-OH-2 | 0 | 12.1 |
| PS-OH-1 | 75 | PS-OH-2 | 25 | 9.7 |
| PS-OH-1 | 50 | PS-OH-2 | 50 | 8.2 |
| PS-OH-1 | 25 | PS-OH-2 | 75 | 7.1 |
| PS-OH-1 | 0 | PS-OH-2 | 100 | 6.4 |

### Example 7

### Formation of Line/Space Patterns

With the use of a TEL ACT8 track, a 200 mm silicon wafer with 155 nm of an organic underlayer was coated with SiARC-1 at a nominal film thickness of 35 nm and subsequently baked at 240° C. for 60 s. The dual layer stack was additionally HMDS primed at 150° C. for 60 s before photoresist application. Photoresist EPIC3013™ was then applied to this stack at a nominal film thickness of 120 nm, and a softbake of 100° C. for 60 s was applied. The complete tri layer stack was then exposed using an ASML1100 193 nm stepper with 0.75 NA 0.89o/0.64i sigma using a 75 nm 150 pitch line/space reticle at fixed dose of 34.0 mJ/cm² and fixed focus of 0.0 μm. A post exposure bake of 100° C. for 60 s was applied prior to develop. The wafer was then developed with CD-26 Developer using a 60 s single puddle, deionized water rinse, and spin dry. Reactive ion etch was then performed using a Plasma Therm 790+ using a mixture of 72 sccm CF₄ and 2 sccm O₂ at 100 W power and 21 mTorr pressure for 120 s.

### Example 8

### Pattern Multiplication Process Using PS-OH Brush as Anti-Spacer Generator (First Composition) and SiARC as Backfilling Material (Second Composition)

A line/space pattern from Example 7 above was overcoated by spin coating a solution of PS-OH brush (2 wt % in propylene glycol monomethyl ether acetate (PGMEA)) at 1500 rpm, baking at 250° C. for 10 min in air. Unattached PS-OH was removed by rinsing the pattern twice with PGMEA and spinning dry. The substrate was then annealed again at 250° C. for 2 min in air. The pattern was imaged by SEM. FIG. 3a showing the lines have grown in CD to 80 nm. The spaces in between lines were then backfilled with SiARC-1 by spin coating at 1671 rpm, followed by baking at 250° C. for 2 min in air. The pattern was then subjected to a two-stage reactive ion etch process using a Plasma Therm 790+ with an initial CHF₃ etch to remove the SiARC overburden (20 sccm CHF₃ at 500 W power and 20 mTorr pressure for 45 s) followed by an O₂ etch to remove the PS (25 sccm O₂ at 100 W power and 6 mTorr pressure for 42 s). The pattern was again imaged by SEM, and a representative micrograph is shown in FIG. 3b, revealing a pattern self-aligned spaces adjacent to the original lines with a CD of only 8 nm at a pitch of 75 nm. This example clearly demonstrates the ability to use a brush material as a sacrificial anti-spacer generator.

### Example 9

### Pattern Multiplication Process Using PS-OH Brush as Anti-Spacer Generator (First Composition) and PDMS as Backfilling Material (Second Composition)

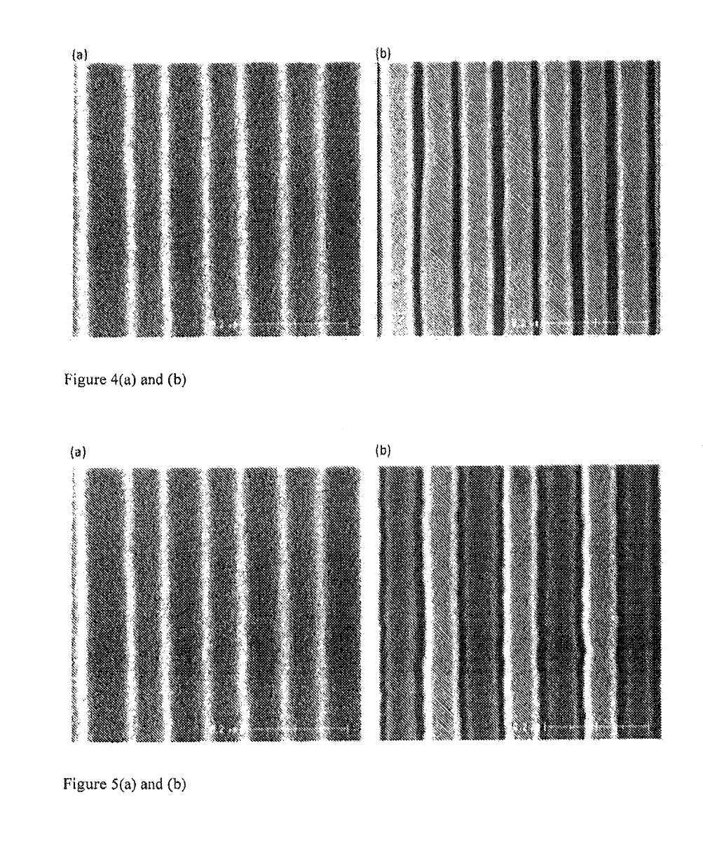

A line/space pattern from Example 7 was overcoated by spin coating a solution of PS-OH brush (2 wt % in propylene glycol monomethyl ether acetate (PGMEA) at 1500 rpm, baking at 250° C. for 10 min in air. Unattached PS-OH was removed by rinsing the pattern twice with PGMEA and spinning dry. The substrate was then annealed again at 250° C. for 2 min in air. The pattern was imaged by SEM, and a representative micrograph is shown in FIG. 4a showing the lines have grown in CD to 80 nm. The spaces in between lines were then backfilled with polydimethylsiloxane (PDMS, 9 kg/mol) by spin coating a solution (0.75 wt % in heptane) at 1760 rpm, followed by baking at 250° C. for 2 min in air. The pattern was then subjected to a two-stage reactive ion etch process using a Plasma Therm 790+ with an initial CHF₃ etch to remove the PDMS overburden (20 sccm CHF₃ at 500 W power and 20 mTorr pressure for 45 s) followed by an O₂ etch to remove the PS (25 sccm O₂ at 100 W power and 6 mTorr pressure for 42 s). The pattern was again imaged by SEM, and a representative micrograph is shown in FIG. 4b, revealing a pattern self-aligned spaces adjacent to the original lines with a CD of only 9 nm at a pitch of 75 nm. This example clearly demonstrates the ability to use a brush material as a sacrificial anti-spacer generator.

### Example 10

### Pattern Multiplication Process Using PMMA-OH-2 Brush as Anti-Spacer Generator (First Composition) and PS as Backfilling Material (Second Composition)

A line/space pattern from Example 7 was overcoated by spin coating a solution of PMMA-OH-2 brush (2 wt % in propylene glycol monomethyl ether acetate (PGMEA)) at 1500 rpm, baking at 250° C. for 10 min in air. Unattached PMMA-OH-2 was removed by rinsing the pattern twice with PGMEA and spinning dry. The substrate was then annealed again at 250° C. for 2 min in air. The pattern was imaged by SEM, and a representative micrograph is shown in FIG. 5a. The spaces in between lines were then backfilled with polystyrene (PS, 33 kg/mol) by spin coating a solution (1.5 wt % in PGMEA) at 1779 rpm, followed by baking at 250° C. for 2 min in air. The pattern was then subjected to a reactive ion etch process with a Plasma Therm 790+ using a mixture of argon and O₂ to remove the PMMA (30 sccm Ar and 10 sccm O₂ at 100 W power and 6 mTorr pressure for 64 s). The pattern was again imaged by SEM, and a representative micrograph is shown in FIG. 5a. This process produced a pattern self-aligned spaces adjacent to the original lines with a CD of only 8 nm at a pitch of 75 nm. This example clearly demonstrates the ability to use a brush material as a sacrificial anti-spacer generator.

### Example 11

### Pattern Multiplication Process Using PMMA-OH-2 Brush as Anti-Spacer Generator (First Composition) and PtBS as Backfilling Material (Second Composition)

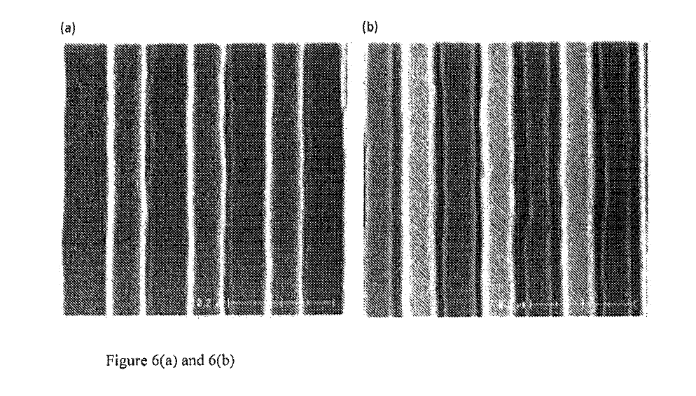

A line/space pattern from Example 7 was overcoated by spin coating a solution of PMMA-OH-2 brush (2 wt % in propylene glycol monomethyl ether acetate (PGMEA) at 1500 rpm, baking at 250° C. for 10 min in air. Unattached PMMA-OH-2 was removed by rinsing the pattern twice with PGMEA and spinning dry. The substrate was then annealed again at 250° C. for 2 min in air. The pattern was imaged by SEM, and a representative micrograph is shown in FIG. 6a. The spaces in between lines were then backfilled with poly(t-butylstyrene) (PtBS, 18.8 kg/mol) by spin coating a solution (1.5 wt % in PGMEA) at 1946 rpm, followed by baking at 250° C. for 2 min in air. The pattern was then subjected to a reactive ion etch process with a Plasma Therm 790+ using a mixture of argon and O₂ to remove the PMMA (30 sccm Ar and 10 sccm O₂ at 100 W power and 6 mTorr pressure for 64 s). The pattern was again imaged by SEM, and a representative micrograph is shown in FIG. 6b. This process produced a pattern self-aligned spaces adjacent to the original lines with a CD of only 9 nm at a pitch of 75 nm. This example shows the ability to use a brush material as a sacrificial anti-spacer generator.

1. A method for forming a relief image, comprising:
a) providing a semiconductor substrate comprising a patterned mask over a layer to be patterned;
b) applying a layer of a first composition over the mask, wherein the composition comprises a polymer and the layer is coated on a sidewall of the mask;
c) applying a layer of a second composition over the semiconductor substrate in a volume adjacent the coated sidewall of the mask; and
d) removing the first composition from the sidewall of the mask, thereby exposing the layer to be patterned and forming a gap between the mask sidewall and the second composition layer to provide a relief image.

2. The method of claim 1 wherein the applied first composition is treated to induce bonding of the first composition to sidewalls of the patterned mask.

3. The method of claim 1 wherein after applying the first composition over the mask, the coated substrate is treated to create a relief image of the patterned mask having the first composition coated on the patterned mask sidewalls.

4. The method of claim 1 wherein the first composition layer is a polymeric brush composition.

5. The method of claim 1 wherein the applied first composition layer is baked and then the baked first composition layer is rinsed.

6. The method of claim 1 wherein a surface of the mask pattern comprises silicon.

7. The method of claim 1 wherein one or more components of the first composition layer form covalent linkages with one or more components of the mask.

8. The method of claim 1 wherein the mask and/or second composition comprises silicon.

9. The method of claim 1 wherein the etch rate of the first composition is at least twice the etch rate of the second composition.

10. A coated substrate comprising:
a semiconductor substrate comprising a patterned mask over a layer to be patterned;
a layer of a first composition over the mask, wherein the composition comprises a polymer brush and the layer is coated on a sidewall of the mask; and
a second composition over the semiconductor substrate in a volume adjacent the coated sidewall of the mask,
wherein the etch rate of the first composition is at least 30 percent greater than the etch rate of each of the 1) first composition and 2) second composition.
